(19) United States
(12) Patent Application Publication
(10) Pub. No.: US 2022/0068750 A1
(43) Pub. Date: Mar. 3, 2022

(54) SEMICONDUCTOR DEVICE AND METHOD OF FORMING THE SAME

(71) Applicant: Intel Corporation, Santa Clara, CA (US)

(72) Inventors: Jenny Shio Yin ONG, Bayan Lepas Pulau (MY); Bok Eng CHEAH, Gelugor Pulau (MY); Seok Ling LIM, Kulim Kedah (MY); Jackson Chung Peng KONG, Tanjung Tokong Pulau (MY)

(21) Appl. No.: 17/090,921

(22) Filed: Nov. 6, 2020

(30) Foreign Application Priority Data
Sep. 1, 2020 (MY) PI2020004490

(51) Int. Cl. H01L 23/367; H01L 23/538

(52) U.S. Cl. CPC H01L 23/367; H01L 23/5386; H01L 23/5385; H01L 23/5384

(57) ABSTRACT

A device including a package substrate and a heat spreader may be provided. The package substrate may include a first surface and an opposing second surface. The package substrate may include a recess extending from the first surface, and a cavity extending from the second surface to the recess. The heat spreader may include a first portion and a second portion arranged on the first portion. The first portion may be arranged within the cavity, and the second portion may be at least partially arranged on the second surface of the package substrate

### CROSS-REFERENCE TO RELATED APPLICATIONS

This non-provisional application claims priority to Malaysian Patent Application No. PI2020004490, which was filed on Sep. 1, 2020, which is incorporated by reference herein in its entirety.

### BACKGROUND

In highly integrated multi-chip packages (MCP), multiple integrated circuit (IC) dies are usually attached on a top surface of a package substrate in a lateral arrangement, and a bottom surface of the package substrate is coupled to a printed circuit board. The package z-height (i.e., the overall package thickness) and real-estate footprint are, however, increased in these multi-chip packages. In addition, electrical performance impairments, e.g., signal latency, attenuation losses, and extensive power loop inductance between the transceiver integrated circuit (IC) dies need to be addressed.

Current solutions for device footprint miniaturization and/or improved electrical performance (e.g., signal latency and attenuation losses) include embedded active silicon and/or 3D stacked IC packaging architectures.

Package real-estate footprint reduction and electrical performance improvement through both 3D IC stacking and embedded active silicon approaches may pose significant thermal dissipation challenges. These approaches also involve device z-height or thickness trade-off with the vertically stacked components and/or increased package stack-up, e.g., package core and/or dielectric thickness to facilitate the assembly of embedded active components.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows a cross-sectional view of a semiconductor device according to an aspect of the present disclosure.

FIG. 2A shows a cross-sectional view of a semiconductor device according to another aspect of the present disclosure.

FIG. 2B shows a top view layout of the semiconductor device according to the aspect as shown in FIG. 2A.

FIG. 3A shows a cross-sectional view of a semiconductor device according to a further aspect of the present disclosure;

FIG. 3B shows a top view layout of the semiconductor device according to the aspect as shown in FIG. 3A.

FIG. 4 shows a flow chart illustrating a method of forming a semiconductor device according to an aspect of the present disclosure.

FIGS. 5A through 5G show cross-sectional views directed to an exemplary process flow for a method of making a semiconductor device according to an aspect of the present disclosure.

FIG. 6 shows an illustration of a computing device that includes a semiconductor device according to a further aspect of the present disclosure.

### DETAILED DESCRIPTION

The following detailed description refers to the accompanying drawings that show, by way of illustration, specific details and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

Advantages of the present disclosure may include improved thermal dissipation of in-package silicon dies through direct heat spreader and thermal interface layer contact, as well as enhanced device thermal hot-spot management.

Another advantage of the present disclosure may include improved electrical performance through shorter interconnects between silicon devices. The improved electrical performance may include a reduction in signal latency, electromagnetic interference and attenuation losses, as well as improvement in power integrity, i.e., reduced power loop inductance between decoupling capacitors and the power delivery network.

Further advantages of the present disclosure may include platform miniaturization through reduced die-to-die device component keep-out-zone, i.e. allowing silicon footprint overlap to achieve compact real estate; and reduction of effective package substrate thickness through a stepped substrate design.

In all aspects, the present disclosure generally relates to a device that may include a package substrate and a heat spreader. The package substrate may include a first surface and an opposing second surface. The package substrate may include a recess extending from the first surface, and a cavity extending from the second surface to the recess. The heat spreader may include a first portion and a second portion arranged on the first portion. The first portion may be arranged within the cavity, and the second portion may be at least partially arranged on the second surface of the package substrate.

The present disclosure generally relates to a method of forming a device. The method may include providing a package substrate including a first surface and an opposing second surface, forming a recess extending from the first surface of the package substrate, forming a cavity extending from the second surface of the package substrate to the recess, forming a first portion of a heat spreader within the cavity, and forming a second portion of the heat spreader on the first portion and at least partially on the second surface of the package substrate.

The present disclosure generally relates to a computing device. The computing device may include a circuit board and a semiconductor package coupled to the circuit board. The semiconductor package may include a package substrate having a first surface and an opposing second surface. The package substrate may include a recess extending from the first surface, and a cavity extending from the second surface to the recess. The semiconductor package may further include a heat spreader having a first portion and a second portion arranged on the first portion. The first portion may be arranged within the cavity, and the second portion may be at least partially arranged on the second surface of the package substrate. The semiconductor package may further include a first die arranged within the recess of the package substrate and a second die arranged on the second surface of the package substrate. The first die may be coupled to the first portion of the heat spreader; and the second portion of the heat spreader may extend to at least partially surround the second die.

To more readily understand and put into practice the aspects of the present semiconductor package, particular aspects will now be described by way of examples and not limitations, and with reference to the figures. For the sake of brevity, duplicate descriptions of features and properties may be omitted.

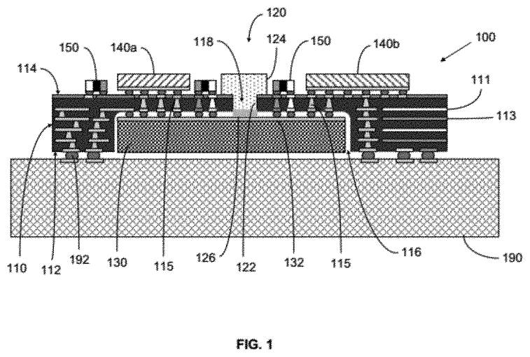

In the aspect shown in FIG. 1, a semiconductor device 100 of the present disclosure is shown in a cross-sectional view layout, including a package substrate 110 and a heat spreader 120. The package substrate 110 may have a first surface 112 (also referred to as a land surface) and an opposing second surface 114 (also referred to as a die surface). As shown in FIG. 1, the package substrate 110 may include a recess 116 extending from the first surface 112 into the package substrate 110 and may include a cavity 118 extending from the second surface 114 to the recess 116. The heat spreader 120 may have a first portion 122 and a second portion 124 arranged on the first portion 122. The first portion 122 may be arranged within the cavity 118, and the second portion 124 may be at least partially arranged on the second surface 114 of the package substrate 110.

The package substrate 110 may include contact pads, electrical interconnects and routings, and other features, for signal routing and electrical connection to various die and components. As shown in FIG. 1, the package substrate 110 may include a plurality of vias 115 for electrical connection, and a plurality of metal planes associated with respective reference voltages, such as a ground reference voltage (Vss) plane 111 and a power supply voltage (Vcc) plane 113. The package substrate 110 may be a coreless substrate without a rigid core layer within the metal layer build-up in an aspect as shown in FIG. 1. In another aspect, the package substrate 110 may include a rigid core layer for improved structural stability.

In the package substrate 110 according to an aspect of the present disclosure, a width of the cavity 118 may be smaller than a width of the recess 116. By way of example, the recess 116 may be configured to accommodate a die, e.g., a first die 130 shown in FIG. 1. With a smaller width of the cavity 118, the heat spreader 120 partially arranged in the cavity 118 may be coupled to a portion of a surface area of the first die 130, leaving out the remaining surface area of the first die 130 for coupling with other components or dies.

In the heat spreader 120, a width of the first portion 122 may be smaller than a width of the second portion 124. As shown in FIG. 1, the second portion 124 may be partially supported on the first portion 122 and may be partially supported on the second surface 114 of the package substrate 110. The second portion 124, which is wider than the first portion 122 and overlaps the second surface 114 of the package substrate 110, may provide mechanical support to improve package warpage control of the semiconductor device 100, also referred to as a semiconductor package 100. The first portion 122 having a smaller dimension may provide additional mechanical support to further improve the package warpage control, through the attachment of the second portion 124 having a larger dimension to provide an anchoring effect. Accordingly, the heat spreader configuration of FIG. 1 may achieve improved package warpage control, compared to a configuration wherein the first portion and the second portion have equivalent width dimensions.

The heat spreader 120 may include a thermally conductive material for thermal dissipation. In an aspect, the first portion 122 and the second portion 124 may both include metal which has sufficient thermal conductivity for thermal dissipation, and at the same time has sufficient stiffness for mechanical support. Examples of metal used in the heat spreader 120 may include but are not limited to stainless steel, aluminum, or gold-coated copper. In another aspect, the first portion 122 may include polymer-metal composites, e.g., a thermal film, or may include nano-fiber composites, e.g., carbon nanotubes, to facilitate thermal dissipation from a die arranged within the recess 116 to the second portion 124 of the heat spreader 120. The first portion 122 and the second portion 124 may be integrally formed or may be two portions attached together. In an aspect, the heat spreader 120 may be further coupled to a heat sink (not shown) for thermal dissipation. In an example, the heat spreader 120 may be coupled to the first die 130 at one side (e.g. at the side of the first portion 122), and may be coupled to the heat sink at an opposite side (e.g. at the side of the second portion 124), to facilitate heat transfer from the first die 130 to the heat sink.

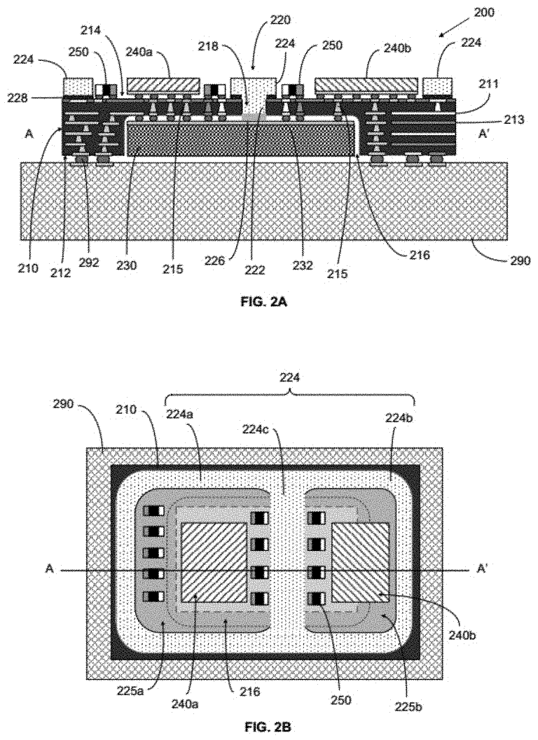

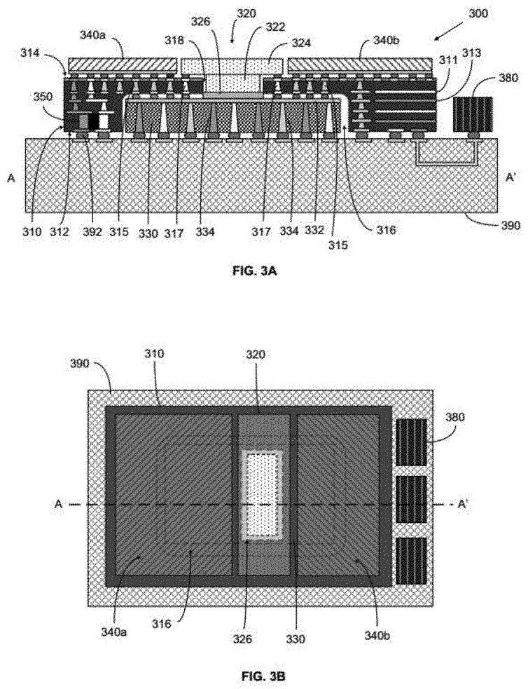

In an aspect, the heat spreader 120 may be a T-shaped structure as shown in FIG. 1. The first portion 122 of the heat spreader 120 may fit into the cavity 118 of the package substrate 110, without any gap between the first portion 122 and the package substrate 110 as shown in FIG. 1. In another aspect, the second portion 124 of the heat spreader 120 may further extend at least partially along a periphery of the package substrate 110 for increased thermal transfer surface area, for example, as shown in FIGS. 2A and 2B below.

In a further aspect of the present disclosure, the heat spreader 120 may be electrically coupled to a reference voltage, e.g., a ground reference voltage. Accordingly, the heat spreader 120 may also be configured as an electrical shield, e.g. a ground shield, to isolate adjacent dies from undesired interferences, such as electromagnetic or radio-frequency interferences. The heat spreader 120 may thus be configured as an integrated ground shield and heat spreader.

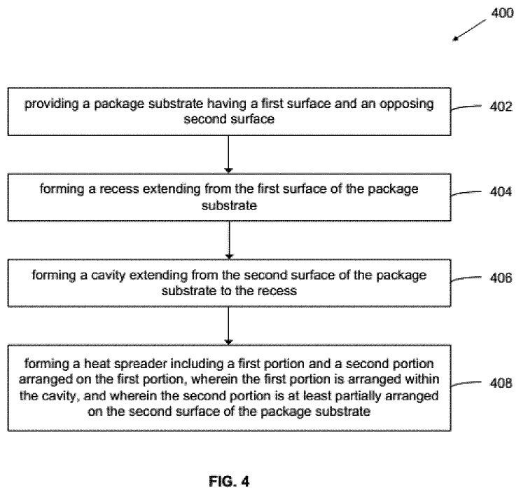

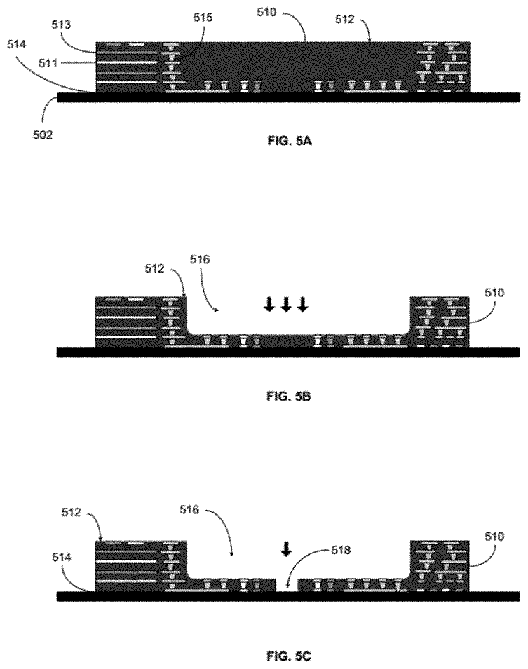

In an aspect, the second portion 124 of the heat spreader 120 may be electrically coupled to a reference voltage plane, e.g., the ground reference voltage (Vss) plane 111, through a plurality of vias in the package substrate 110, wherein the plurality of vias are arranged under the second portion 124 of the heat spreader 120 as will be illustrated in FIG. 3A below. In another aspect, the heat spreader 120 may be coupled to the reference voltage through the first die 130, as will be illustrated in FIG. 3A below.

According to an aspect, the device 100 may include the first die 130 arranged within the recess 116 of the package substrate 110, where the first die 130 may be coupled to the first portion 122 of the heat spreader 120. The first die 130 may be a silicon die, such as but not limited to a central processing unit (CPU) or a system-on-chip (SOC). In an aspect, the first die 130, e.g., a silicon active layer 132 of the first die 130, may be physically coupled to the first portion 122 of the heat spreader 120 through a thermal interface layer 126 arranged therebetween. The thermal interface layer 126, e.g. solder thermal paste or adhesives, may facilitate thermal transfer and mechanical support, i.e. mechanical contact with the first die 130. In another aspect, the first die 130 may be in direct contact with the first portion 122 of the heat spreader 120 or may be coupled to the first portion 122 of the heat spreader 120 through a solder layer.

According to a further aspect of the present disclosure, the device 100 may further include one or more second dies (e.g., 140a and 140b) arranged on the second surface 114 of the package substrate 110. The second portion 124 of the heat spreader 120 may extend to at least partially surround each of the second dies 140a, 140b. According to an aspect of the present disclosure, the second dies 140a, 140b may be separated from each other by the second portion 124 of the heat spreader 120. In an example as shown in FIG. 1, the second portion 124 of the heat spreader 120 may be arranged or extend to surround an edge of the respective second dies 140a, 140b, a top view of which may be similar to a top view of a heat spreader 320 arranged relative to the second dies 340a, 340b as shown in FIG. 3B below. In this example, the second portion 124 of the heat spreader 120 may be in the shape of a strip parallel to an edge of the respective second dies 140a, 140b, where the strip-like second portion 124 may be arranged between the second dies 140a, 140b. In another example as shown in FIGS. 2A and 2B below, the second portion of the heat spreader 120 may further extend to form a respective frame to surround each of the second dies 140a, 140b as described in more detail below.

Although FIG. 1 shows two second dies 140a, 140b, it should be understood that only one second die or more than two second dies may be arranged on the second surface 114 of the package substrate 110 according to various aspects of the present disclosure.

The second dies 140a, 140b may be various types of semiconductor dies. The second dies 140a and 140b may be the same type of semiconductor dies, or may be different types of semiconductor dies. In an example, the second die 140a may be a memory device, such as dynamic random access memory (DRAM) or other memory devices. In another example, the second die 140b may be a graphic processing unit (GPU), a field programmable gate array (FPGA), or a radio frequency integrated circuit (RFIC) device.

As shown in FIG. 1, each of the second dies 140a, 140b may be electrically coupled to the first die 130 through the plurality of vias 115 provided in the package substrate 110, wherein the plurality of vias 115 are arranged between the first die 130 and the second dies 140a, 140b. The direct vertical interconnection between the first die 130 and the respective second die 140a, 140b provides a shorter interconnection, which improves signal latency and signal integrity, and reduces attenuation losses (e.g., signal crosstalk coupling and impedance discontinuities) compared to conventional die-to-die lateral routing interconnection. In an example, the vertical interconnection between the first die 130 and the respective second die 140a, 140b may range from about 15 μm to about 75 μm, compared to horizontal die-to-die interconnection length which ranges from about 0.5 mm to about 20 mm.

In an aspect of the present disclosure, the device 100 may include one or more capacitors 150 arranged on the second surface 114 of the package substrate 110. The one or more capacitors 150 may be electrically coupled to at least one of the first die 130 or the second dies 140a, 140b, for example, through a plurality of routing traces provided in the package substrate 110. The capacitors 150 may also be coupled to reference planes associated with respective reference voltages, e.g., the ground reference voltage (Vss) plane 111 and/or the power supply voltage (Vcc) plane 113. The capacitors 150 may be referred to as decoupling capacitors. In an example, the capacitors 150 may have a capacitance in a range from about 100 nF to about 1 uF to filter frequency noise ranging from about 20 MHz to about 100 MHz. Through the direct and shortened distance between the decoupling capacitor and the power delivery network of the silicon devices, power AC loop inductance is reduced and hence power integrity is improved.

In an example, the capacitors 150 may be arranged between the heat spreader 120 and the respective second die 140a, 140b. In another example, the capacitors 150 may be arranged between the respective second die and the periphery of the package substrate 110.

According to various aspects illustrated in FIG. 1, a stepped packaging architecture is provided where multiple dies may be arranged in a more compact manner along with the arrangement of the heat spreader, so as to form a thermally efficient and compact multi-chip package 100. The semiconductor package 100 may be coupled to a circuit board 190, e.g., a motherboard, through solder balls 192 and associated contact pads.

FIG. 2A shows a cross-sectional view of a semiconductor device 200 along line A-A′ of FIG. 2B according to another aspect of the present disclosure, and FIG. 2B shows a top view layout of the semiconductor device 200 according to the aspect as shown in FIG. 2A.

Many of the aspects of the semiconductor device 200 are the same or similar to those of the semiconductor device 100. For the sake of brevity, duplicate descriptions of features and properties are omitted. Accordingly, it will be understood that the descriptions of any feature and/or property relating to FIG. 2A and FIG. 2B that are the same or similar to a feature and/or property in FIG. 1 will have those descriptions be applicable hereinbelow as well.

In the aspect shown in FIG. 2A, a semiconductor device 200 of the present disclosure is shown in a cross-sectional view layout, including a package substrate 210 and a heat spreader 220. The package substrate 210 may have a first surface 212 and an opposing second surface 214. The package substrate 210 may include a recess 216 extending from the first surface 212 into the package substrate 210 and may include a cavity 218 extending from the second surface 214 to the recess 216. The heat spreader 220 may have a first portion 222 and a second portion 224 arranged on the first portion 222. The first portion 222 may be arranged within the cavity 218, and the second portion 224 may be at least partially arranged on the second surface 214 of the package substrate 210.

The package substrate 210 may include contact pads, electrical interconnects and routings, and other features, for signal routing and electrical connection to various die and components. As shown in FIG. 2A, the package substrate 210 may include a plurality of vias 215 for electrical connection, and a plurality of metal planes associated with respective reference voltages, such as a ground reference voltage (Vss) plane 211 and a power supply voltage (Vcc) plane 213.

According to an aspect of the present disclosure, a width of the cavity 218 may be smaller than a width of the recess 216. By way of example, the recess 216 may be configured to accommodate a die, e.g., a first die 230 shown in FIG. 2A. The heat spreader 220 partially arranged in the cavity 218 may be coupled to a portion of a surface area of the first die 230, leaving out the remaining surface area of the first die 230 for coupling with other components or dies. In an aspect, the first portion 222 of the heat spreader 220 may fit into the cavity 218 of the package substrate 210, without any gap between the first portion 222 and the package substrate 210.

In the heat spreader 220, a dimension (e.g., width) of the first portion 222 may be smaller than a dimension (e.g., width) of the second portion 224 arranged thereon. As shown in FIG. 2A, the second portion 224 may be partially supported on the first portion 222 and may be partially supported on the second surface 214 of the package substrate 210. The second portion 224, which is wider than the first portion 222 and overlaps the second surface 214 of the package substrate 210, may provide mechanical support to improve package warpage control of the semiconductor device 200, also referred to as a semiconductor package 200.

According to an aspect of the present disclosure, the second portion 224 of the heat spreader 220 may further extend at least partially along a periphery of the package substrate 210 for increased thermal transfer surface area. In an aspect as shown in the top view of FIG. 2B, the second portion 224 may further extend completely around the periphery of the package substrate 210, to form a first frame portion 224a and a second frame portion 224b. The first frame portion 224a may define a first frame cavity 225a configured to accommodate or enclose a die, e.g., one of second dies 240a therein. The second frame portion 224b may define a second frame cavity 225b configured to accommodate or enclose a die therein, e.g. another one of second dies 240b. The first frame portion 224a and the second frame portion 224b may overlap or coincide at 224c which is the part of the second portion 224 arranged on and in direct contact with the first portion 222. Although FIG. 2B shows the frame portions 224a, 224b in a rectangular shape, it is understood that the frame portions 224a, 224b may be in any other suitable shape depending on the location and arrangement of the dies and components on the package substrate 210. In an example, the second portion 224 may only include one frame portion 224a or 224b to at least partially surround one of the second dies 240a, 240b. In another example, one or more of the frame portions 224a, 224b may only partially surround the second dies 240a, 240b, for example, along some but not all edges of the respective second dies 240a, 240b. In a further example, the second portion 224 may extend partially along the periphery of the package substrate 210, so that one or more of the second dies 240a, 240b may be only partially surrounded by the frame portion 224a, 224b.

According to various aspects, the first portion 222 having a smaller dimension than the second portion 224 may provide additional mechanical support to further improve the package warpage control, through the attachment of the second portion 224 having a larger dimension to provide an anchoring effect. In addition, the extension parts 224a, 224b of the second portion 224 arranged on the second surface 214 of the package substrate 210 may provide additional mechanical support for the package 200. Accordingly, the heat spreader configuration of FIGS. 2A and 2B may achieve further improved package warpage control, compared to a configuration wherein the first portion and the second portion have equivalent width dimensions and compared to the heat spreader 120 of FIG. 1.

Similar to the heat spreader 120, the heat spreader 220 may include a thermally conductive material for thermal dissipation. In an aspect, the first portion 222 and the second portion 224 may both include metal which has sufficient thermal conductivity for thermal dissipation, and at the same time has sufficient stiffness for mechanical support. Examples of metal used in the heat spreader 220 may include but are not limited to stainless steel, aluminum, or gold-coated copper. In another aspect, the first portion 222 may include polymer-metal composites, e.g., a thermal film, or may include nano-fiber composites, e.g., carbon nanotubes, to facilitate thermal dissipation from a die arranged within the recess 216 to the second portion 224 of the heat spreader 220. The first portion 222 and the second portion 224 may be integrally formed or may be two portions attached together.

In a further aspect of the present disclosure, the heat spreader 220 may be electrically coupled to a reference voltage, e.g., a ground reference voltage. Accordingly, the heat spreader 220 may also be configured as an electrical shield, e.g., a ground shield, to isolate adjacent dies from undesired interferences, such as electromagnetic or radio-frequency interferences. The heat spreader 220 may thus be configured as an integrated ground shield and heat spreader.

In an aspect, the second portion 224 of the heat spreader 220 may be electrically coupled to a reference voltage plane, e.g., the ground reference voltage (Vss) plane 211, through a plurality of vias in the package substrate 210, wherein the plurality of vias are arranged under the second portion 224 of the heat spreader 220 as will be illustrated in FIG. 3A below. In another aspect, the heat spreader 220 may be coupled to the reference voltage through the first die 230, as will be illustrated in FIG. 3A below.

Similar to FIG. 1, the device 200 may include the first die 230 arranged within the recess 216 of the package substrate 210, where the first die 230 may be coupled to the first portion 222 of the heat spreader 220. The first die 230 may be a silicon die, such as but not limited to a central processing unit (CPU) or a system-on-chip (SOC). In an aspect, the first die 230, e.g., a silicon active layer 232 of the first die 230, may be physically coupled to the first portion 222 of the heat spreader 220 through a thermal interface layer 226 arranged therebetween. The thermal interface layer 226, e.g., solder thermal paste or adhesives, may facilitate thermal transfer and mechanical support, i.e. mechanical contact with the first die 230. In another aspect, the first die 230 may be in direct contact with the first portion 222 of the heat spreader 220 or may be coupled to the first portion 222 of the heat spreader 220 through a solder layer.

According to a further aspect of the present disclosure, the device 200 may further include one or more second dies (240a, 240b) arranged on the second surface 214 of the package substrate 210. The second portion 224 of the heat spreader 220 may extend to at least partially surround each of the second dies 240a, 240b, as illustrated in FIG. 2B. According to an aspect of the present disclosure, the second dies 240a, 240b may be separated from each other by the second portion 224 of the heat spreader 220. In an example as shown in FIG. 2B, the second portion 224 of the heat spreader 220 may extend to form the first frame portion 224a and the second frame portion 224b, to surround the respective second dies 240a, 240b. In other words, the second die 240a may be arranged within the first frame cavity 225a, and the second die 240b may be arranged within the second frame cavity 225b. The first frame portion 224a and the second frame portion 224b may overlap or coincide at 224c which is the part of the second portion 224 arranged on and in direct contact with the first portion 222 and which may separate the second dies 240a, 240b from each other. In an aspect, the first frame portion 224a, the second frame portion 224b and the overlapping portion 224c arranged on and in direct contact with the first portion 222, may be coupled to the second surface 214 of the package substrate 210 through an adhesive layer 228. In an aspect, the adhesive layer 228 may be a conductive adhesive layer e.g., an anisotropic conductive film or a solder layer to facilitate electrical connection to the ground reference voltage (Vss) plane 211 in the package substrate 210.

It should be understood that only one second die or more than two second dies may be arranged on the second surface 214 of the package substrate 210 according to various aspects of the present disclosure.

The second dies 240a, 240b may be various types of semiconductor dies. In an example, the second die 240a may be a memory device, such as dynamic random access memory (DRAM) or other memory devices. In another example, the second die 240b may be a graphic processing unit (GPU), a field programmable gate array (FPGA), or a radio frequency integrated circuit (RFIC) device.

As shown in FIG. 2A, each of the second dies 240a, 240b may be electrically coupled to the first die 230 through the plurality of vias 215 provided in the package substrate 210, wherein the plurality of vias 215 are arranged between the first die 230 and the second dies 240a, 240b. The direct vertical interconnection between the first die 230 and the respective second die 240a, 240b provides a shorter interconnection, which improves signal latency and signal integrity, and reduces attenuation losses (e.g., signal crosstalk coupling and impedance discontinuities) compared to conventional die-to-die lateral routing interconnection.

In an aspect of the present disclosure, the device 200 may include one or more capacitors 250 arranged on the second surface 214 of the package substrate 210. The one or more capacitors 250 may be electrically coupled to at least one of the first die 230 or the second dies 240a, 240b, for example, through a plurality of routing traces provided in the package substrate 210. The capacitors 250 may also be coupled to reference planes associated with respective reference voltages, e.g., the ground reference voltage (Vss) plane 211 and/or the power supply voltage (Vcc) plane 213. In an aspect as shown in FIGS. 2A and 2B, the capacitors 150 may be arranged within the first frame cavity 225a and/or the second frame cavity 225b. The capacitors 250 may be referred to as decoupling capacitors. In an example, the capacitors 250 may have a capacitance in a range from about 100 nF to about 1 uF to filter frequency noise ranging from about 20 MHz to about 100 MHz. Through the direct and shortened distance between the decoupling capacitor and the power delivery network of the silicon devices, power AC loop inductance is reduced and hence power integrity is improved.

According to various aspects of FIGS. 2A and 2B, the outline of the second portion 224 of the heat spreader 220 may be configured to at least partially surround one or more adjacent electronic components and/or dies for increased thermal transfer surface area and/or electrical shielding among the one or more electronic components and dies.

The semiconductor package 200 may be coupled to a circuit board 290, e.g., a motherboard, through solder balls 292 and associated contact pads.

FIG. 3A shows a cross-sectional view of a semiconductor device 300 along line A-A′ of FIG. 3B according to a further aspect of the present disclosure, and FIG. 3B shows a top view layout of the semiconductor device 300 according to the aspect as shown in FIG. 3A.

Many of the aspects of the semiconductor device 300 are the same or similar to those of the semiconductor device 100, 200. For the sake of brevity, duplicate descriptions of features and properties are omitted. Accordingly, it will be understood that the descriptions of any feature and/or property relating to FIG. 3A and FIG. 3B that are the same or similar to a feature and/or property in FIG. 1, FIG. 2A and FIG. 2B will have those descriptions be applicable hereinbelow as well.

In the aspect shown in FIG. 3A, a semiconductor device 300 of the present disclosure is shown in a cross-sectional view layout, including a package substrate 310 and a heat spreader 320. The package substrate 310 may have a first surface 312 and an opposing second surface 314. The package substrate 310 may include a recess 316 extending from the first surface 312 into the package substrate 310 and may include a cavity 318 extending from the second surface 314 to the recess 316. The heat spreader 320 may have a first portion 322 and a second portion 324 arranged on the first portion 322. The first portion 322 may be arranged within the cavity 318, and the second portion 324 may be at least partially arranged on the second surface 314 of the package substrate 310.

The package substrate 310 may include contact pads, electrical interconnects and routings, and other features, for signal routing and electrical connection to various die and components. As shown in FIG. 3A, the package substrate 310 may include a plurality of vias 315 for electrical connection, and a plurality of metal planes associated with respective reference voltages, such as a ground reference voltage (Vss) plane 311 and a power supply voltage (Vcc) plane 313.

According to an aspect of the present disclosure, a width of the cavity 318 may be smaller than a width of the recess 316. By way of example, the recess 316 may be configured to accommodate a die, e.g., a first die 330 shown in FIG. 3A. The heat spreader 320 partially arranged in the cavity 318 may be coupled to a portion of a surface area of the first die 330, leaving out the remaining surface area of the first die 330 for coupling with other components or dies. In an aspect as shown in FIG. 3A, the first portion 322 of the heat spreader 320 may be arranged within the cavity 318 of the package substrate 310 with a gap between the first portion 322 and the package substrate 310. In another aspect, the first portion 322 may fit into the cavity 318 of the package substrate 310 without any gap therebetween as shown in FIG. 1 and FIG. 2A above.

Similar to the heat spreader 120 of FIG. 1, a dimension (e.g., width) of the first portion 322 of the heat spreader 320 may be smaller than a dimension (e.g., width) of the second portion 324 arranged thereon. As shown in FIG. 3A, the heat spreader 320 may be a T-shaped structure, similar to the heat spreader 120 shown in FIG. 1. In another aspect, the heat spreader 320 may have its second portion 324 further extending at least partially along a periphery of the package substrate 310 for increased thermal transfer surface area, mechanical support and/or electrical shielding, similar to the heat spreader 220 shown in FIGS. 2A and 2B.

The second portion 324, which is wider than the first portion 322 and overlaps the second surface 314 of the package substrate 310, may provide mechanical support to improve package warpage control of the semiconductor device 300, also referred to as a semiconductor package 300. According to various aspects, the first portion 322 having a smaller dimension than the second portion 324 may provide additional mechanical support to further improve the package warpage control, through the attachment of the second portion 324 having a larger dimension to provide an anchoring effect. Accordingly, the heat spreader configuration of FIGS. 3A and 3B may achieve improved package warpage control, compared to a configuration wherein the first portion and the second portion have equivalent width dimensions.

Similarly, the heat spreader 320 may include a thermally conductive material for thermal dissipation. In an aspect, the first portion 322 and the second portion 324 may both include metal both for thermal dissipation and for mechanical support. In another aspect, the first portion 322 may include polymer-metal composites or nano-fiber composites, to facilitate thermal dissipation from a die arranged within the recess 316 to the second portion 324 of the heat spreader 320. The first portion 322 and the second portion 324 may be integral or may be two portions attached together.

In a further aspect of the present disclosure, the heat spreader 320 may be electrically coupled to a reference voltage, e.g., a ground reference voltage. Accordingly, the heat spreader 320 may also be configured as an electrical shield, e.g., a ground shield, to isolate adjacent dies from undesired interferences, such as electromagnetic or radio-frequency interferences. Hence, the heat spreader 320 may be configured as an integrated ground shield and heat spreader.

As shown in FIG. 3A, the second portion 324 may be partially supported on the first portion 322 and may be partially supported on the second surface 314 of the package substrate 310. The second portion 324 may be electrically coupled to a reference voltage plane, e.g., the ground reference voltage (Vss) plane 311, through a plurality of vias 317 (e.g., micro-vias) in the package substrate 310 along with associated solder balls and contact pads for reference voltage connection. The plurality of vias 317 may be arranged under the second portion 324 of the heat spreader 320, as shown in FIG. 3A.

The device 300 may further include the first die 330 arranged within the recess 316 of the package substrate 310, where the first die 330 may be coupled to the first portion 322 of the heat spreader 320. The first die 330 may be a silicon die, such as but not limited to a central processing unit (CPU) or a system-on-chip (SOC). In an aspect, the first die 330, e.g., a silicon active layer 332 of the first die 330, may be physically coupled to the first portion 322 of the heat spreader 320 through a thermal interface layer 326 arranged therebetween. The thermal interface layer 326, e.g. solder thermal paste or adhesives, may facilitate thermal transfer and mechanical support, i.e. mechanical contact with the first die 330. In another aspect, the first die 330 may be in direct contact with the first portion 322 of the heat spreader 320 or may be coupled to the first portion 322 of the heat spreader 320 through a solder layer.

According to an aspect as shown in FIG. 3A, the first die 330 may include a plurality of through-silicon-vias (TSVs) 334. The TSVs 334 may be configured to facilitate signal transmission among various dies, for example, among the first die 330 and one or more second dies 340a, 340b arranged on the package substrate 310. In another aspect, the TSVs 334 may be configured to facilitate a power supply connection. The power supply connection from the motherboard 390 to the second dies 340a, 340b may be mainly achieved through package vias, package metal layers and/or passive components. The plurality of TSVs 334 may carry additional power supply from a motherboard 390 to the silicon dies (e.g., one or more of the second dies 340a, 340b) of the compact multi-chip package 300.

In a further aspect, the plurality of TSVs 334 may be configured to carry a reference voltage (e.g. the ground voltage) to the heat spreader 320, e.g., from the motherboard 390. Accordingly, the heat spreader 320 is also configured as a ground (Vss) shield to isolate undesired interferences (e.g., electromagnetic or radio-frequency interferences) from the adjacent silicon dies.

As shown in FIGS. 3A and 3B, one or more second dies (340a, 340b) may be arranged on the second surface 314 of the package substrate 310. The second portion 324 of the heat spreader 320 may extend to at least partially surround each of the second dies 340a, 340b. According to an aspect of the present disclosure, the second dies 340a, 340b may be separated from each other by the second portion 324 of the heat spreader 320.

It should be understood that only one second die or more than two second dies may be arranged on the second surface 314 of the package substrate 310 according to various aspects of the present disclosure.

The second dies 340a, 340b may be various types of semiconductor dies. In an example, the second die 340a may be a memory device, such as dynamic random access memory (DRAM) or other memory devices. In another example, the second die 340b may be a graphic processing unit (GPU), a field programmable gate array (FPGA), or a radio frequency integrated circuit (RFIC) device.

As shown in FIG. 3A, each of the second dies 340a, 340b may be electrically coupled to the first die 330 through the plurality of vias 315 provided in the package substrate 310, wherein the plurality of vias 315 are arranged between the first die 330 and the second dies 340a, 340b. The direct vertical interconnection between the first die 330 and the respective second die 340a, 340b provides a shorter interconnection, which improves signal latency and signal integrity, and reduces attenuation losses (e.g., signal crosstalk coupling and impedance discontinuities) compared to conventional die-to-die lateral routing interconnection.

In an aspect of FIG. 3A, the device 300 may include one or more capacitors 350 arranged in the package substrate 310. The one or more capacitors 350 may be electrically coupled to at least one of the first die 330 or the second dies 340a, 340b, for example, through a plurality of routing traces provided in the package substrate 310. The capacitors 350 may also be coupled to reference planes associated with respective reference voltages, e.g., the ground reference voltage (Vss) plane 311 and/or the power supply voltage (Vcc) plane 313. In an example, the capacitors 350 may have a capacitance in a range from about 100 nF to about 1 uF to filter frequency noise ranging from about 20 MHz to about 100 MHz. In another example, the capacitors 350 may have a capacitance in a range from about 1 uF to about 47 uF to filter power noise in lower frequency range, i.e. from about 1 MHz to about 20 MHz.

The semiconductor package 300 may be coupled to a circuit board 390, e.g., a motherboard, through solder balls 392 and associated contact pads. The first die 330 may also be electrically coupled to the motherboard 390 through solder balls and associated contact pads. One or more voltage regulators (VR) 380 may be arranged on the motherboard 390 and may be coupled to the package substrate 310 through solder balls and the motherboard 390. The voltage regulators 380 may be configured to supply power to the first die 330 and/or the second dies 340a, 340b through, for example, the power supply voltage (Vcc) plane 313.

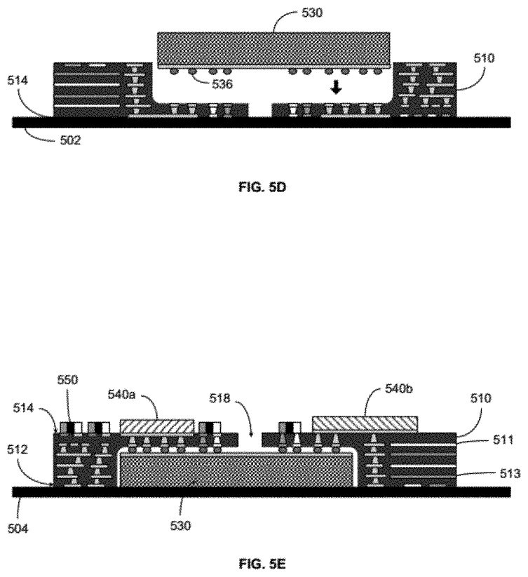

FIG. 4 shows a flowchart 400 illustrating a method of forming a device, such as the device 100, 200, 300 of FIGS. 1, 2A-2B, and 3A-3B, according to an aspect of the present disclosure. Various aspects described with reference to FIGS. 1, 2A-2B, and 3A-3B may be similarly applied for the method of FIG. 4.

At 402, a package substrate having a first surface and an opposing second surface may be provided.

At 404, a recess extending from the first surface of the package substrate may be formed.

At 406, a cavity extending from the second surface of the package substrate to the recess may be formed.

At 408, a heat spreader is formed, including a first portion and a second portion arranged on the first portion. The first portion may be arranged within the cavity. The second portion may be at least partially arranged on the second surface of the package substrate.

In an aspect, the first portion and the second portion may be formed as an integral piece. In an example, the first portion and the second portion may be integrally formed within the cavity and on the second surface of the package substrate. In another example, the integral piece of the heat spreader may be formed and then arranged on the package substrate, with the first portion arranged within the cavity and the second portion at least partially arranged on the second surface of the package substrate.

In another aspect, the first portion and the second portion may be formed as separate pieces. In an example, the separate pieces may be attached to each other to form the heat spreader, which may be arranged on the package substrate with the first portion arranged within the cavity and the second portion at least partially arranged on the second surface of the package substrate. In another example, the first portion may be formed within the cavity, and the second portion may be formed on the first portion and on the second surface of the package substrate.

It should be understood that the order of forming the first portion, the second portion, the entire heat spreader, and the arrangement thereof on the package substrate may be varied depending on the process and design requirements, according to various aspects of the present disclosure,

According to an aspect of the present disclosure, the second portion of the heat spreader may be formed to further extend at least partially along a periphery of the package substrate.

It will be understood that the operations described above relating to FIG. 4 are not limited to this particular order. Any suitable, modified order of operations may be used.

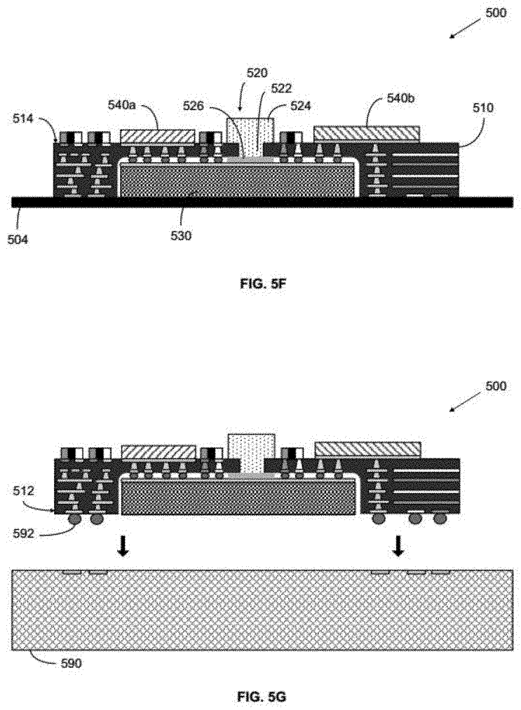

FIGS. 5A through 5G show cross-sectional views directed to an exemplary process flow for a method of making a semiconductor device (e.g., the device 100, 200, 300) according to an aspect of the present disclosure. Various aspects described with reference to FIGS. 1, 2A-2B, and 3A-3B may be similarly applied for the process flow of FIG. 5A-5G.

In FIG. 5A, a package substrate 510 may be provided. The package substrate 510 having a plurality of metal and dielectric build-up layers may be attached onto a carrier 502, e.g., through a hot-press or lamination process. The package substrate 510 may have a first surface 512 and an opposing surface 514, wherein the second surface 514 is in contact with the carrier 502. In an aspect, an adhesive layer may be disposed in between the carrier 502 and the second surface 514 for improved adhesion. The package substrate 510 may include contact pads, electrical interconnects and routings, and other features, for signal routing and electrical connection to various die and components. As shown in FIG. 5A, the package substrate 510 may include a plurality of vias 515 for electrical connection, and a plurality of metal layers associated with respective reference voltages, such as a ground reference voltage (Vss) plane 511 and a power supply voltage (Vcc) plane 513. The package substrate 510 may be a coreless substrate without a rigid core layer within the metal layer build-up in an aspect as shown in FIG. 5A. In another aspect, the package substrate 510 may include a rigid core layer for improved structural stability.

In FIG. 5B, a recess 516 may be formed in the package substrate 510, for example, through a laser or mechanical drilling process. The recess 516 may extend from the first surface 512 of the package substrate 510. In another aspect, the recess 516 may be formed through an etching process e.g., a chemical etching process.

In FIG. 5C, a cavity 518 may be formed under the recess 516, i.e., from the bottom surface of the recess 516 to the second surface 514 of the package substrate 510. In other words, the cavity 518 extends from the second surface 514 of the package substrate 510 to the recess 516. The cavity 518 may be formed through a laser or mechanical drilling process. In an aspect, the cavity 518 may be formed with a smaller width than the recess 516, as described above.

In FIG. 5D, a first die 530 may be arranged within the recess 516. The first die 530 may be attached to the bottom surface of the recess 516 through solder bumps 536, for example, through a solder reflow or thermal compression bonding process.

In FIG. 5E, the first carrier 502 attached to the second surface 514 of the package substrate 510 may be removed, and the package substrate 510 may be flipped over to attach to a second carrier 504 at the first surface 512 of the package substrate 510. The first die 530 may also be attached to the second carrier 504.

According to an aspect, one or more dies and/or components may be arranged or attached on the second surface 514 of the package substrate, for example, through a solder reflow or thermal compression bonding process. As shown in FIG. 5E, a plurality of second dies 540a, 540b, and capacitors 550 are arranged on the second surface 514 of the package substrate. In an example, the second die 540a may be a memory die, and the second die 540b may be an FPGA die. The cavity 518 may be located between the second die 540a and the second die 540b.

In FIG. 5F, a heat spreader 520 may be formed at least partially within the cavity 518. A first portion 522 of a heat spreader 520 may be formed within the cavity 518, and a second portion 524 of the heat spreader 520 may be formed on the first portion 522 and at least partially on the second surface 514 of the package substrate 510. In an aspect, the first portion 522 and the second portion 524 may be formed by disposing metal within the cavity 518 and at least partially on the second surface 514 of the package substrate 510, e.g., through a hot-press, solder reflow and/or thermal compression bonding process. In another aspect, the first portion 522 may be formed as a thermal film within the cavity 518, and the second portion 524 may be formed as a metal piece attached to the first portion 522. In an aspect, the first portion 522 and the second portion 524 may be an integral conductive piece which may include a stainless steel layer, a copper layer, a gold-coated copper layer, or an aluminium layer.

In an aspect as shown in FIG. 5F, a thermal interface layer 526 may be formed between the first die 530 and the first portion 522 of the heat spreader 520. In an aspect, the thermal interlayer layer 526 may be formed on the first die 530 during the process in FIG. 5D. In another aspect, the first portion 522 may be attached to the first die 530 through a solder layer, or may be directly formed or arranged on the first die 530.

After the process in FIG. 5F, a semiconductor device 500 or a semiconductor package 500, which is similar to the device 100 of FIG. 1, may be formed with the arrangement of the package substrate 510, the heat spreader 520, and the respective dies 530, 540a, 540b described according to various aspect above. It is understood that the semiconductor device 500 similar to the device 200, 300 of FIGS. 2A-2B and 3A-3B may also be formed according to the above processes, e.g., with corresponding changes in the shape/arrangement of the heat spreader 520, or by electrically coupling the heat spreader 520 to a reference voltage, etc.

In FIG. 5G, the second carrier 504 attached to the first surface 512 of the package substrate may be removed, and solder balls 592 may be formed on the first surface 512 of the package substrate. The semiconductor device 500 may be mounted onto a motherboard 590, e.g., through a solder reflow process.

The fabrication methods and the choice of materials are intended to permit the present semiconductor packages to improve thermal/electrical performance and device miniaturization. It will be apparent to those ordinary skilled practitioners that the foregoing process operations may be modified without departing from the scope of the present disclosure.

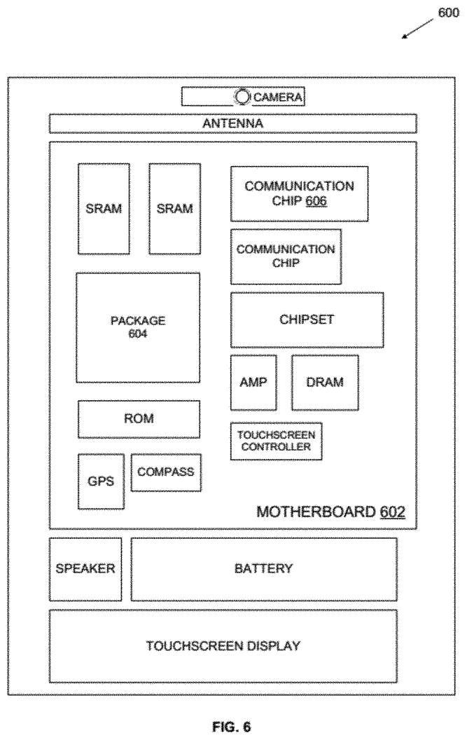

Aspects of the present disclosure may be implemented into a system using any suitable hardware and/or software. FIG. 6 schematically illustrates a computing device 600 that may include a semiconductor package 100, 200, 300, 500 as described herein, in accordance with some aspects. The computing device 600 may house a board such as a motherboard 602. The motherboard 602 may include several components, including but not limited to a semiconductor package 604, according to the present disclosure, and at least one communication chip 606. The semiconductor package 604, which may include a package substrate configured to accommodate various dies as well as a heat spreader configured for thermal dissipation and/or electrical shielding according to the present disclosure, may be physically and electrically coupled to the motherboard 602. In some implementations, the at least one communication chip 606 may also be physically and electrically coupled to the motherboard 602.

Depending on its applications, computing device 600 may include other components that may or may not be physically and electrically coupled to the motherboard 602. These other components may include, but are not limited to, volatile memory (e.g., DRAM), non-volatile memory (e.g., ROM), flash memory, a graphics processor, a digital signal processor, a cryptoprocessor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth). In another aspect, the semiconductor package 604 of the computing device 600 may be assembled with a plurality of passive devices, as described herein.

The communication chip 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some aspects they might not. The communication chip 606 may implement any of several wireless standards or protocols, including but not limited to Institute for Electrical and Electronics Engineers (IEEE) standards including Wi-Fi (IEEE 502.11 family), IEEE 502.16 standards (e.g., IEEE 502.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 502.16 compatible BWA networks are generally referred to as WiMAX networks, an acronym that stands for Worldwide Interoperability for Microwave Access, which is a certification mark for products that pass conformity and interoperability tests for the IEEE 502.16 standards.

The communication chip 606 may also operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 606 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 606 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 606 may operate in accordance with other wireless protocols in other aspects.

The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

In various implementations, the computing device 600 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In an aspect, the computing device 600 may be a mobile computing device. In further implementations, the computing device 600 may be any other electronic device that processes data.

### EXAMPLES

Example 1 may include a device including a package substrate and a heat spreader; the package substrate having a first surface and an opposing second surface, a recess extending from the first surface, and a cavity extending from the second surface to the recess; the heat spreader having a first portion and a second portion arranged on the first portion, wherein the first portion may be arranged within the cavity, and the second portion may be at least partially arranged on the second surface of the package substrate.

Example 2 may include the subject matter of Example 1, wherein a width of the cavity may be smaller than a width of the recess.

Example 3 may include the subject matter of Example 1 or 2, wherein a width of the first portion may be smaller than a width of the second portion.

Example 4 may include the subject matter of any one of Example 1 to 3, wherein the second portion of the heat spreader may further extend at least partially along a periphery of the package substrate.

Example 5 may include the subject matter of any one of Example 1 to 4, wherein the heat spreader may be electrically coupled to a reference voltage.

Example 6 may include the subject matter of Example 5, wherein the reference voltage includes a ground voltage.

Example 7 may include the subject matter of Example 5 or 6, wherein the second portion of the heat spreader may be electrically coupled to a reference voltage plane associated with the reference voltage through a plurality of vias in the package substrate, wherein the plurality of vias are arranged under the second portion of the heat spreader.

Example 8 may include the subject matter of any one of Example 1 to 7, further including a first die arranged within the recess of the package substrate, wherein the first die is coupled to the first portion of the heat spreader.

Example 9 may include the subject matter of Example 8, further including a thermal interface layer arranged between the first die and the first portion of the heat spreader.

Example 10 may include the subject matter of Example 8 or 9, further including one or more second dies arranged on the second surface of the package substrate, wherein the second portion of the heat spreader may extend to at least partially surround each of the second dies.

Example 11 may include the subject matter of Example 10, wherein each of the second dies is electrically coupled to the first die through a plurality of vias.

Example 12 may include the subject matter of Example 10 or 11, wherein the second dies may be separated from each other by the second portion of the heat spreader.

Example 13 may include the subject matter of any one of Example 10 to 12, wherein the first die may include a plurality of through silicon vias configured to carry a power supply voltage to at least one of the second dies.

Example 14 may include the subject matter of any one of Example 10 to 12, wherein the first die may include a plurality of through silicon vias configured to carry a reference voltage to the heat spreader.

Example 15 may include the subject matter of any one of Example 10 to 14, further including one or more capacitors arranged on the second surface of the package substrate, wherein the one or more capacitors are electrically coupled to at least one of the first die or the second dies.

Example 16 may include the subject matter of any one of Example 1 to 15, wherein the first portion of the heat spreader may include at least one of metal, polymer-metal composites, or nano-fiber composites.

Example 17 may include the subject matter of any one of Example 1 to 16, wherein the second portion of the heat spreader may include metal.

Example 18 may include the subject matter of any one of Example 1 to 17, wherein the first portion and the second portion of the heat spreader are integrally formed.

Example 19 may include a method of forming a device, the method including providing a package substrate having a first surface and an opposing second surface; forming a recess extending from the first surface of the package substrate; forming a cavity extending from the second surface of the package substrate to the recess; forming a heat spreader including a first portion and a second portion arranged on the first portion, wherein the first portion is arranged within the cavity, and wherein the second portion is at least partially arranged on the second surface of the package substrate.

Example 20 may include the subject matter of Example 19, further including further extending the second portion of the heat spreader at least partially along a periphery of the package substrate.

Example 21 may include a computing device having a circuit board and a semiconductor package coupled to the circuit board; the semiconductor package including a package substrate having a first surface and an opposing second surface; the package substrate including a recess extending from the first surface, and a cavity extending from the second surface to the recess; the semiconductor package further including a heat spreader having a first portion and a second portion arranged on the first portion, wherein the first portion may be arranged within the cavity and the second portion may be at least partially arranged on the second surface of the package substrate; the semiconductor package further including a first die arranged within the recess of the package substrate and a second die arranged on the second surface of the package substrate; wherein the first die may be coupled to the first portion of the heat spreader; and the second portion of the heat spreader may extend to at least partially surround the second die.

Example 22 may include the subject matter of Example 21, wherein the second portion of the heat spreader may further extend at least partially along a periphery of the package substrate.

Example 23 may include the subject matter of Example 21 or 22, in which the computing device is a mobile computing device further including one or more of an antenna, a display, a touchscreen display, a touchscreen controller, a battery, a power amplifier, a global positioning system (GPS) device, a compass, a speaker, and/or a camera coupled with the circuit board.

In a further example, any one or more of examples 1 to 23 may be combined.

These and other advantages and features of the aspects herein disclosed will be apparent through reference to the above description and the accompanying drawings. Furthermore, it is to be understood that the features of the various aspects described herein are not mutually exclusive and can exist in various combinations and permutations.

It will be understood that any property described herein for a specific device may also hold for any device described herein. It will also be understood that any property described herein for a specific method may hold for any of the methods described herein. Furthermore, it will be understood that for any device or method described herein, not necessarily all the components or operations described will be enclosed in the device or method, but only some (but not all) components or operations may be enclosed.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

While the present disclosure has been particularly shown and described with reference to specific aspects, it should be understood by those skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. A device comprising:
a package substrate including a first surface and an opposing second surface, wherein the package substrate comprises:
a recess extending from the first surface, and
a cavity extending from the second surface to the recess; and
a heat spreader including a first portion and a second portion on the first portion, wherein the first portion is within the cavity, and wherein the second portion is at least partially on the second surface of the package substrate.

2. The device of claim 1, wherein a width of the cavity is smaller than a width of the recess.

3. The device of claim 1, wherein a width of the first portion of the heat spreader is smaller than a width of the second portion of the heat spreader.

4. The device of claim 1, wherein the second portion of the heat spreader further extends at least partially along a periphery of the package substrate.

5. The device of claim 1, wherein the heat spreader is electrically coupled to a reference voltage.

6. The device of claim 5, wherein the second portion of the heat spreader is electrically coupled to a reference voltage plane associated with the reference voltage through a plurality of vias in the package substrate, wherein the plurality of vias are under the second portion of the heat spreader.

7. The device of claim 1, further comprising a first die within the recess of the package substrate, wherein the first die is coupled to the first portion of the heat spreader.

8. The device of claim 7, further comprising a thermal interface layer between the first die and the first portion of the heat spreader.

9. The device of claim 7, further comprising one or more second dies on the second surface of the package substrate, wherein the second portion of the heat spreader extends to at least partially surround each of the second dies.

10. The device of claim 9, wherein each of the second dies is electrically coupled to the first die through a plurality of vias.

11. The device of claim 9, wherein the second dies are separated from each other by the second portion of the heat spreader.

12. The device of claim 9, wherein the first die comprises a plurality of through-silicon-vias configured to carry a power supply voltage to at least one of the second dies.

13. The device of claim 9, wherein the first die comprises a plurality of through-silicon-vias configured to carry a reference voltage to the heat spreader.

14. The device of claim 9, further comprising one or more capacitors on the second surface of the package substrate, wherein the one or more capacitors are electrically coupled to at least one of the first die or the second dies.

15. The device of claim 1, wherein the first portion of the heat spreader comprises at least one of metal, polymer-metal composites, or nano-fiber composites.

16. The device of claim 1, wherein the second portion of the heat spreader comprises metal.

17. A method comprising:
providing a package substrate including a first surface and an opposing second surface;
forming a recess extending from the first surface of the package substrate;
forming a cavity extending from the second surface of the package substrate to the recess;
forming a heat spreader including a first portion and a second portion arranged on the first portion, wherein the first portion is arranged within the cavity, and wherein the second portion is at least partially arranged on the second surface of the package substrate.

18. The method of claim 17, further comprising:
further extending the second portion of the heat spreader at least partially along a periphery of the package substrate.

19. A computing device comprising:
a circuit board; and
a semiconductor package coupled to the circuit board, wherein the semiconductor package further comprises:
a package substrate including a first surface and an opposing second surface, wherein the package substrate comprises a recess extending from the first surface, and a cavity extending from the second surface to the recess;
a heat spreader including a first portion and a second portion on the first portion, wherein the first portion is within the cavity, and wherein the second portion is at least partially on the second surface of the package substrate;
a first die within the recess of the package substrate, wherein the first die is coupled to the first portion of the heat spreader; and
a second die on the second surface of the package substrate, wherein the second portion of the heat spreader extends to at least partially surround the second die.

20. The computing device of claim 19, wherein the second portion of the heat spreader further extends at least partially along a periphery of the package substrate.
